(19) United States
(12) Patent Application Publication
(10) Pub. No.: US 2026/0286516 A1
(43) Pub. Date: Sep. 24, 2026

(54) AN ATOMIC LAYER DEPOSITION APPARATUS AND A METHOD FOR COATING A SUBSTRATE

(71) Applicant: Beneq Oy, Espoo (FI)

(72) Inventors: Alexander PERROS, Espoo (FI); Zhen ZHU, Espoo (FI)

(21) Appl. No.: 19/474,606

(22) PCT Filed: Apr. 10, 2024
(86) PCT No.: PCT/FI2024/050160

§ 371 Date: Oct. 10, 2025

(30) Foreign Application Priority Data
Apr. 11, 2023 (FI) 20235406

(51) Int. Cl. C23C 16/455; H01J 37/32

(52) U.S. Cl. CPC C23C 16/45519; C23C 16/45536; C23C 16/45548; C23C 16/45565; H01J 37/32449

(57) ABSTRACT

An atomic layer deposition apparatus and a method in which the apparatus comprising a reaction chamber, an electrode assembly arranged in connection with a top wall, a counter electrode arranged opposite the electrode assembly, a reaction zone is formed between the electrode assembly and the counter electrode, a precursor supply opening via which the precursors are supplied to the reaction space, a connecting element arranged between the electrode assembly and the top wall, a dielectric layer provided on an inner surface of the top wall, and a gap formed between a upper surface of the electrode assembly and the dielectric layer for providing a flow path for a blocking gas to prevent a precursor film formation.

### FIELD OF THE INVENTION

The present invention relates to an atomic layer deposition apparatus for processing a surface of a substrate successively with at least a first precursor and a second precursor according to principles of atomic layer deposition and more particularly to an apparatus as defined in the preamble of the independent claim 1.

The present invention also relates to a method for coating a substrate in a plasma ALD reaction chamber by subjecting a surface of the substrate to successive surface reactions of a first precursor and a second precursor according to the principles of atomic layer deposition in the reaction chamber as defined in the preamble of the independent claim 11.

### BACKGROUND OF THE INVENTION

In the prior art solutions, when conductive coatings are deposited in a plasma ALD reaction chamber, coatings are formed not only on the surface that is the subject of deposition but also to the walls of the reaction chamber. When a coating forms between the electrode and the wall of the reaction chamber, connecting the two, an electrical shorting occurs.

### BRIEF DESCRIPTION OF THE INVENTION

An object of the present invention is to provide an apparatus and method which solves or at least alleviates the disadvantages of the prior art.

The objects of the invention are achieved by an apparatus and a method which are characterized by what is stated in the independent claims. The preferred embodiments of the invention are disclosed in the dependent claims.

The invention is based on the idea of providing a dielectric layer and a blocking gas flow flowing in connection with the dielectric layer to prevent the film formation between the reaction chamber and the electrode assembly so as to prevent electrical shorting.

According to the present invention an atomic layer deposition apparatus for processing a surface of a substrate successively with at least a first precursor and a second precursor according to principles of atomic layer deposition comprising a reaction chamber having a top wall, a bottom wall and at least one side wall, said walls forming a reaction space inside the reaction chamber. The apparatus further comprising an electrode assembly arranged in connection with the top wall, a counter electrode arranged opposite the electrode assembly at a distance from said electrode assembly such that a reaction zone is formed between the electrode assembly and the counter electrode, and a precursor supply opening via which the precursors are supplied to the reaction space. The apparatus further comprising a connecting element arranged between the electrode assembly and the top wall of the reaction chamber such that the electrode assembly is connected to the top wall through the connecting element, a dielectric layer provided on an inner surface of the top wall of the reaction chamber, a gap formed between an upper surface of the electrode assembly and the dielectric layer of the inner surface of the top wall of the reaction chamber for providing a flow path for a blocking gas to prevent a precursor film formation between the electrode assembly and the reaction chamber, and a gas supply opening that opens into the gap for supplying blocking gas from a blocking gas channel to the gap. The gap extending between the connecting element and an outer perimeter of the electrode assembly and is open to the reaction space through the outer perimeter of the electrode assembly.

In other words, the electrode assembly and the counter electrode are arranged apart from each other such that the reaction zone, in which the reactions occur during plasma ALD process, is formed between the electrode assembly and the counter electrode. The counter electrode is a grounded electrode while the electrode assembly is powered. The precursor supply opening provides a flow path for precursors from a precursor source into the reaction space inside the reaction chamber. The electrode is connected to the top wall of the reaction chamber with a connecting element such that the connecting element is arranged between the top wall of the reaction chamber and the electrode. Thereby, a gap is formed between the top wall of the reaction chamber and the electrode. The distance between the top wall of the reaction chamber and the electrode is preferably only some millimetres, for example 0,2-5 mm and preferably 0,3-2 mm, so that the maximum distance between the top wall of the reaction chamber and the electrode is 5 mm, and preferably 2 mm, and the minimum distance between the top wall of the reaction chamber and the electrode is only 0,2 mm, and preferably 0,3 mm. The top wall comprises a dielectric layer, which may be in the form of a dielectric coating or a dielectric plate or dielectric sheet or any other dielectric covering that covers the top wall so that the top wall is covered with an electrical insulator preventing electric charges flowing through the covering. The gap formed between the top wall of the reaction chamber and the electrode assembly is thereby formed between the dielectric layer on the top wall of the reaction chamber and the upper surface of the electrode assembly. The gas supply opening opens into the gap providing therefore a flow path for the blocking gas from the blocking gas channel to the gap. The gas supply opening, providing a flow path for the blocking gas to the gap, together with the dielectric layer prevent precursor gases entering from the reaction zone to the gap and especially prevent formation of the coating to the connection between the top wall of the reaction chamber and the electrode assembly thereby preventing the possibility for electrical shorting. The gap, which is provided between the upper surface of the electrode assembly and the dielectric layer provided on the inner surface of the top wall of the reaction chamber, extends parallel to the upper surface of the electrode assembly between the connecting element and the outer perimeter of the electrode assembly. The connecting element may comprise additional structures that shorten the length of the gap, so that the gap extends from the outer perimeter of the electrode assembly to the structures of the connecting element and possible structures surrounding it which form the opposite end of the gap in relation to the outer perimeter of the electrode assembly. The outer perimeter of the electrode assembly is the edge of the electrode assembly which is closest to the at least one side wall of the reaction chamber. In other words, the outer perimeter of the electrode assembly forms an end edge of the upper surface of the electrode assembly. The gap is open to the reaction space through the outer perimeter of the electrode assembly in such a way that the electrode assembly is arranged at a distance from the at least one side wall of the reaction chamber, whereby a flow path of the blocking gas from the gap to the reaction space is formed between the at least one side wall and the electrode assembly. The electrode assembly has an outer perimeter surface which means that the flow path for the blocking gas is formed between the at least one side wall of the reaction chamber and the outer perimeter surface of the electrode assembly.

According to the invention the blocking gas channel is arranged to extend inside the electrode assembly such that the gas supply opening is provided at the upper surface of the electrode assembly through which the blocking gas is supplied from the blocking gas channel to the gap.

In other words, the gas supply opening is arranged at the upper surface of the electrode assembly opening through the upper surface of the electrode assembly into the gap, and the blocking gas channel extends inside the electrode assembly such that the blocking gas channel is in flow connection with a gas source outside the reaction chamber. The gas source may provide inert gas as the blocking gas or precursor gas as the blocking gas.

According to the invention the blocking gas channel is arranged to extend through the top wall of the reaction chamber such that the gas supply opening is provided at the inner surface of the top wall of the reaction chamber having the dielectric layer through which the blocking gas is supplied from the blocking gas channel to the gap.

In other words, the gas supply opening is arranged at the inner surface of the top wall of the reaction chamber opening through the top wall of the reaction chamber into the gap, and the blocking gas channel extends inside the top wall of the reaction chamber such that the blocking gas channel is in flow connection with a gas source outside the reaction chamber. The gas source may provide inert gas as the blocking gas or precursor gas as the blocking gas. In a preferred embodiment of the invention a vacuum chamber surrounds the reaction chamber, and the blocking gas channel extends through the top wall of the reaction chamber between the gap and the vacuum chamber, and the blocking gas supplied through the blocking gas channel is the inert gas in the vacuum chamber.

According to the invention the gas supply opening is arranged closer to the connecting element than the outer perimeter of the electrode assembly.

In other words, the gas supply opening providing the flow path for the blocking gas from the blocking gas channel to the gap is provided at the upper surface of the electrode assembly such that the gas supply opening is at the upper surface of the electrode assembly closer to the connecting element than the outer perimeter of the electrode assembly, and preferably next to the connecting element at the upper surface of the electrode assembly.

According to the invention the electrode assembly comprises the upper surface which is towards the top wall of the reaction chamber, a under surface which is towards the bottom wall of the reaction chamber and a perimeter surface which is towards the at least one side wall of the reaction chamber. The electrode assembly is arranged at a distance from the at least one side wall such that the flow path extends from the first gap past the outer perimeter of the upper surface of the electrode assembly to a second gap between the perimeter surface of the electrode assembly and the at least one side wall of the reaction chamber.

In other words, the flow path for the blocking gas extends inside the reaction chamber from the gas supply opening through the gap between the upper surface of the electrode assembly and the inner surface of the top wall of the reaction chamber comprising the dielectric layer, i.e., along the first gap extending parallel to the upper surface of the electrode assembly, to the gap between the at least one side wall of the reaction chamber and the outer perimeter surface of the electrode assembly, i.e., the second gap extending parallel to the at least one side wall of the reaction chamber. Thereby the first gap and the second gap extend in transverse directions relative to each other.

According to the invention the dielectric layer is arranged to extend from the inner surface of the top wall of the reaction chamber to the at least one side wall of the reaction chamber.

In other words, the dielectric layer covers the inner surface of the top wall of the reaction chamber and extends to the inner surface of the at least one side wall of the reaction chamber. In a preferred embodiment of the invention there is no discontinuity in the dielectric layer when moving from the top wall to the at least one side wall. The dielectric layer is preferably provided at the at least one side wall of the reaction chamber in an area opposite the outer perimeter surface of the electrode assembly.

According to the invention the dielectric layer is arranged to extend from the inner surface of the top wall of the reaction chamber to the at least one side wall of the reaction chamber so that the second gap is formed between the dielectric layer at the at least one side wall of the reaction chamber and the perimeter surface of the electrode assembly.

In other words, the dielectric layer covers the inner surface of the top wall of the reaction chamber and extends to the inner surface of the at least one side wall of the reaction chamber. In a preferred embodiment of the invention there is no discontinuity in the dielectric layer when moving from the top wall to the at least one side wall. The dielectric layer is preferably provided at the at least one side wall of the reaction chamber in an area opposite the outer perimeter surface of the electrode assembly so that the dielectric layer is provided along the area of the second gap.

According to the invention the apparatus further comprises a showerhead for supplying precursors to the reaction space, said showerhead comprises the precursor supply opening and the electrode assembly.

In other words, the apparatus comprises a showerhead which is a nozzle that supplies precursors through multiple precursor supply openings to the reaction space inside the reaction chamber. The precursor supply opening is thereby provided at the showerhead. The showerhead comprises a supply surface having the precursor supply opening. The supply surface is toward the counter electrode so that the reaction zone is formed between the supply surface of the showerhead and the counter electrode. The showerhead further comprises the electrode assembly as part of the showerhead. The electrode assembly forms the upper part of the showerhead having the upper surface of the electrode assembly towards the top wall of the reaction chamber.

According to the invention the apparatus further comprises a blocking gas channel having a gas supply opening that opens into the gap for supplying blocking gas from the blocking gas channel to the gap, and said blocking gas channel is arranged to extend inside the showerhead such that the gas supply opening is provided at the upper surface of the electrode assembly through which the blocking gas is supplied from the blocking gas channel to the gap.

In other words, the blocking gas channel extends inside the showerhead for providing blocking gas from a gas source to the gap between the upper surface of the electrode assembly and the dielectric layer on the inner surface of the top wall of the reaction chamber. The blocking gas channel extending inside the showerhead may be a separate gas channel from a precursor supply channel which extends inside the showerhead and forms a flow connection with the reaction space through the precursor supply opening for supplying precursor from a precursor source to the reaction zone, or alternatively the blocking gas channel may be part of the precursor supply channel supplying precursor from the precursor source outside the reaction chamber both to the reaction zone and to the gap. The precursor supplied to the gap does not form the film without the plasma, or without a co-reactant precursor or co-reactant precursors, which is performed at the reaction zone.

According to the invention the apparatus further comprises a vacuum chamber, the reaction chamber is arranged inside the vacuum chamber.

In other words, the vacuum chamber surrounds the reaction chamber.

According to the present invention in the method for coating a substrate in a plasma ALD reaction chamber by subjecting a surface of the substrate to successive surface reactions of a first precursor and a second precursor according to the principles of atomic layer deposition in the reaction chamber, the reaction chamber comprising a top wall, a bottom wall and at least one side wall, said walls forming a reaction space inside the reaction chamber, an electrode assembly arranged in connection with the top wall, a counter electrode arranged opposite the electrode assembly at a distance from said electrode assembly, a reaction zone provided between the electrode assembly and the counter electrode, and a precursor supply opening via which the precursors are supplied to the reaction zone. The method comprises arranging a substrate in the reaction zone, supplying blocking gas from a blocking gas channel through a gas supply opening to a gap formed between a upper surface of the electrode assembly and a dielectric layer provided on an inner surface of the top wall, supplying precursor from a precursor gas source through the precursor supply opening to the reaction zone, directing the blocking gas along the gap towards the reaction zone for preventing the precursor from entering the gap, and generating plasma discharge to the reaction zone with the electrode assembly.

In other words, the method comprises a step of supplying the blocking gas from the blocking gas channel through the gas supply opening to the gap which is formed between the inner surface of the top wall of the reaction chamber having the dielectric layer and the upper surface of the electrode assembly. The method further comprises a step of supplying precursor from a precursor source through the precursor supply opening to the reaction zone, the precursor supply opening may be provided for example to the at least one side wall of the reaction chamber such that the precursor is supplied toward opposite side wall or to a showerhead arrange in connection with the top wall of the reaction chamber such that the precursor is supplied toward the counter electrode. The method further comprises a step of directing the blocking gas along the gap, i.e., in a direction parallel to the top wall of the reaction chamber having the dielectric layer or alternatively or in addition in a direction parallel to the upper surface of the electrode assembly. The method further comprises a step of directing the blocking gas towards the reaction zone, which means that supplying the blocking gas along the gap and further at the end of the gap parallel to the surface of the at least one side wall of the reaction chamber towards the reaction zone, which is on the opposite side of the electrode assembly to the upper surface.

According to the invention the method further comprises supplying precursor from the precursor gas source to a showerhead having the precursor supply opening and supplying the precursor further from the showerhead through the precursor supply opening to the reaction zone.

In other words, the step of supplying precursor comprises supplying precursor through a showerhead in which the precursor supply opening is provided. The showerhead preferably comprises multiple precursor supply openings. The method comprises supplying precursor from the showerhead through the precursor supply opening to the reaction zone which is provided between the showerhead and the counter electrode, the showerhead comprising the electrode assembly.

According to the invention the method further comprises supplying the precursor from the precursor source through the blocking gas channel to the gap as the blocking gas, and further supplying the precursor from the precursor source through the precursor supply opening to the reaction zone as a plasma gas.

In other words, the method comprises a step of supplying blocking gas into the gap, which the blocking gas is a precursor, and supplying the same precursor also to the reaction zone through the precursor supply opening. The precursor supplied into the reaction zone is activated by the plasma in the reaction zone to form a film on the surface of the substrate, while the precursor supplied into the gap does not form a film on the inner surface of the top wall of the reaction chamber or on the upper surface of the electrode assembly because it is not activated by plasma when supplied to the gap.

According to the invention the method further comprises supplying inert gas from an inert gas source through the blocking gas channel to the gap as the blocking gas.

In other words, the method comprises a step of supplying blocking gas into the gap, which the blocking gas is an inert gas such as nitrogen gas (N²).

According to the invention the reaction chamber is arranged inside a vacuum chamber and, the method further comprises supplying inert gas from the vacuum chamber through the top wall of the reaction chamber to the gap.

In other words, the method comprises a step of supplying inert gas from the vacuum chamber surrounding the reaction chamber to the gap through a blocking gas channel extending through the top wall of the reaction chamber. The inert gas is the inert gas that prevails in the vacuum chamber.

According to the invention the method further comprises directing the blocking gas along the gap outside from a perimeter of the upper surface of the electrode assembly, and further along a path between an outer perimeter surface of the electrode assembly and the at least one side wall of the reaction chamber towards the reaction zone.

In other words, the method comprises a step of directing the blocking gas along the gap parallel to the top wall of the reaction chamber to the outer perimeter of the upper surface of the electrode assembly and further along the surface of the at least one side wall toward the reaction zone. This means that the method comprises supplying the blocking gas along the top wall of the reaction chamber up to the area of the corner of the reaction chamber and from there along the surface of the at least one side wall of the reaction chamber, which protects the surfaces of the reaction chamber from film formation by active precursors coming from the reaction zone.

According to the invention the method is performed with an apparatus as described above.

An advantage of the invention is that the dielectric layer and the blocking gas together prevent film formation on the surfaces of the reaction chamber and prevent the possibility of electrical shorting between the electrode assembly and the reaction chamber due to electrically conductive coatings.

### BRIEF DESCRIPTION OF THE DRAWINGS

The invention is described in detail by means of specific embodiments with reference to the enclosed drawings, in which

FIG. 1 shows the apparatus according to the invention;

FIG. 2 shows the apparatus according to the invention as seen from above;

FIG. 3 shows the apparatus according to the invention having a dielectric layer also at the side wall;

FIG. 4 shows the apparatus according to the invention having the gas supply opening at the top wall;

FIG. 5 shows the apparatus according to the invention having the showerhead and a dielectric layer also at the side wall;

FIG. 6 shows the apparatus according to the invention having the showerhead; and

FIG. 7 shows the apparatus of the invention having a different geometry.

### DETAILED DESCRIPTION OF THE INVENTION

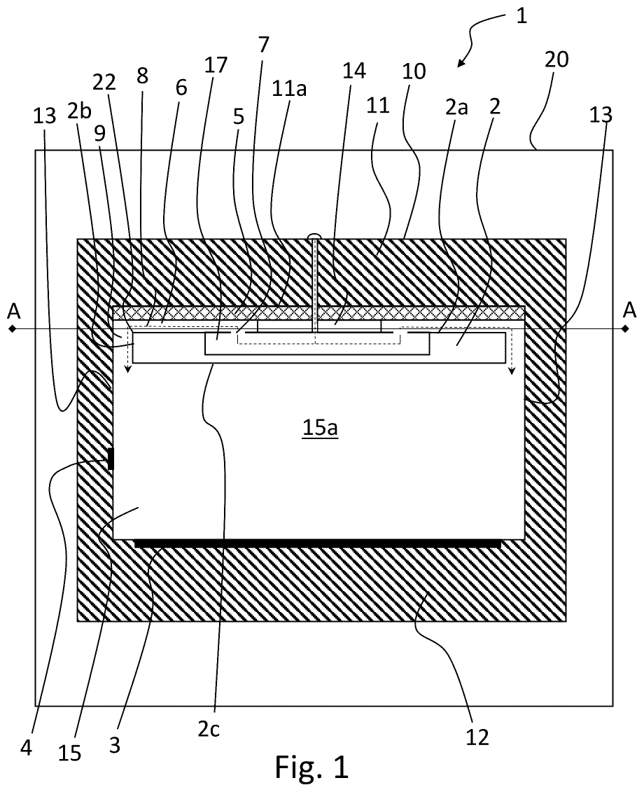

FIG. 1 shows an apparatus 1 according to the invention having a reaction chamber 10 and a vacuum chamber 20 surrounding the reaction chamber 10. The reaction chamber 10 having a top wall 11, a bottom wall 12 and at least one side wall 13 which said walls forming a reaction space 15 inside the reaction chamber 10. The apparatus 1 further comprises an electrode assembly 2 arranged in connection with the top wall 11. The electrode assembly 2 having an upper surface 2a facing toward the top wall 11 of the reaction chamber 10, an outer perimeter 22 having an outer perimeter surface 2b facing toward the at least one side wall 13 of the reaction chamber 10 and a under surface 2c facing toward the bottom wall 12. The reaction chamber 10 further comprises a counter electrode 3 arranged opposite to the electrode assembly 2 at a distance from the electrode assembly 2 such that a reaction zone 15a is formed between the electrode assembly 2 and the counter electrode 3. The counter electrode 3 is preferably provided in connection with the bottom wall 12. The reaction chamber 10 further comprises a precursor supply opening 4 via which the precursors are supplied into the reaction space 15 and especially into the reaction zone 15a. The apparatus 1 further comprises a connecting element 14 which connects the electrode assembly 2 to the top wall 11 of the reaction chamber 10. The apparatus 1 also comprises a dielectric layer 5 arranged on an inner surface 11a of the top wall 11 of the reaction chamber 10. A gap 6 is formed between the top wall 11 of the reaction chamber 10 and the electrode assembly 2. In other words, the gap 6 is formed between the dielectric layer 5 provided on the inner surface 11a of the top wall 11 and the upper surface 2a of the electrode assembly 2. All this above described applies to the apparatus shown in all the FIGS. 1-6.

FIG. 1 further shows a gas supply opening 7 formed at the upper surface 2a of the electrode assembly 2 which the gas supply opening 7 opens into the gap 6 for supplying blocking gas from a blocking gas channel 17 to the gap 6. The blocking gas channel 17 extends inside the electrode assembly 2 and is in flow connection with a gas source outside the reaction chamber 10. The blocking gas channel 17 can extend from the inside of the electrode assembly 2 through the connecting element 14 and further outside of the reaction chamber 10 and outside of the vacuum chamber 20 to the gas source. A flow path 8 of the blocking gas when supplied out from the gas supply opening 7 at the upper surface 2a of the electrode assembly 2 extends along the gap 6 parallel to the dielectric layer 5 to the outer perimeter 22 of the electrode assembly 2 and along the outer perimeter surface 2b of the electrode assembly 2 towards the reaction zone 15. In FIG. 1 the precursor supply opening 4 is arranged at the side wall 13 of the reaction chamber 10.

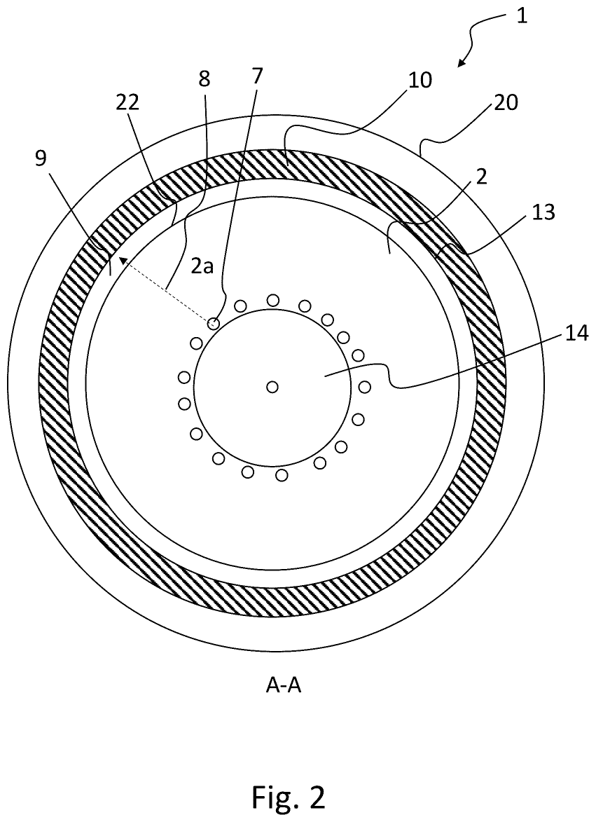

FIG. 2 shows the apparatus 1 shown in FIG. 1 as seen from above along the line A-A as seen in FIG. 1. The apparatus 1 has a round geometry in this example having the vacuum chamber 20 around the reaction chamber 10, which the reaction chamber 10 having the side wall 13. The connecting element 14 forms the connection to the top wall of the reaction chamber 10 (not shown in the figure). The electrode assembly 2 has the upper surface 2a along which the blocking gas flows toward the outer perimeter 22 of the electrode assembly 2 and past the outer perimeter 22 of the electrode assembly 2 to a second gap between the at least one side wall 13 and the outer perimeter surface 2b of the electrode assembly 2. In this example the gas supply opening 7 is provided at the upper surface 2a of the electrode assembly 2 next to the connecting element 14. However, the gas supply opening 7 is preferably always provided closer to the connecting element or the end of the gap 6 than the outer perimeter 22 of the electrode assembly 2.

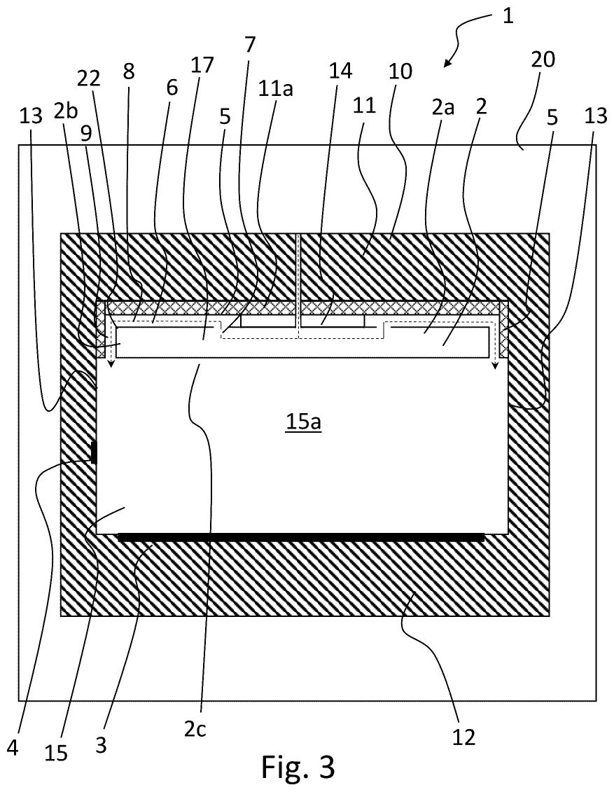

FIG. 3 shows otherwise the same structure of the apparatus 1 as shown in FIG. 1 but the dielectric layer 5 extends also to the at least one side wall 13 of the reaction chamber 10. The dielectric layer 5 extends preferably along the length of the second gap 9 between the side wall 13 and the outer perimeter surface 2b of the electrode assembly 2. In FIG. 3 the precursor supply opening 4 is arranged at the side wall 13 of the reaction chamber 10.

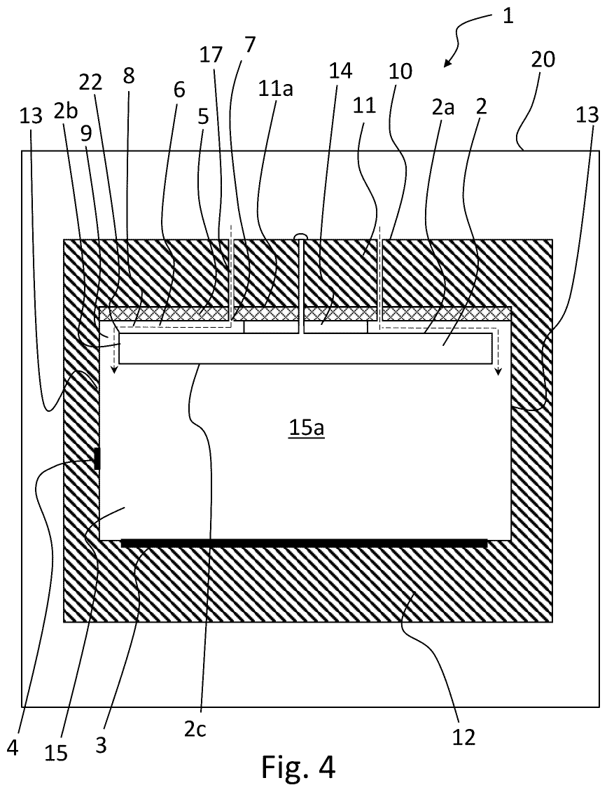

FIG. 4 shows otherwise the same structure of the apparatus 1 as shown in FIG. 1 but the gas supply opening 7 is provided at the top wall 11 of the reaction chamber 10 and the blocking gas channel 17 extends through the top wall 11 of the reaction chamber 10 from the vacuum chamber 20 to the gap 6. The gas supply opening 7 is provided closer to the connecting element 14 than the outer perimeter 22 of the electrode assembly 2. In FIG. 4 the precursor supply opening 4 is arranged at the side wall 13 of the reaction chamber 10.

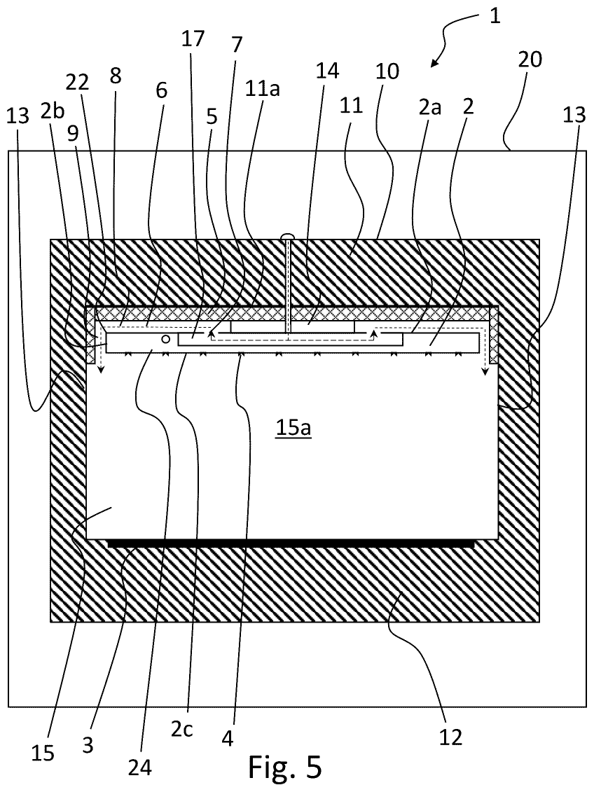

FIG. 5 shows the apparatus 1 according to the invention having the same structural components as described in connection with the FIG. 1 and said to apply to all figures. The apparatus shown in FIG. 5 further comprises a showerhead 24 having the precursor supply opening 4 through which the precursor is supplied to the reaction zone 15 provided between the showerhead 24 and the counter electrode 3. The showerhead 24 comprises also the electrode assembly 2 having the upper surface 2a, the outer perimeter surface 2b and the under surface 2c. The gas supply opening 7 is formed at the upper surface 2a of the electrode assembly 2 which the gas supply opening 7 opens into the gap 6 for supplying blocking gas from a blocking gas channel 17 to the gap 6. As the electrode assembly 2 is part of the showerhead 24 the blocking gas channel 17 extends inside the showerhead 24 and is in flow connection with a gas source outside the reaction chamber 10 and outside the vacuum chamber 20. The blocking gas channel 17 can extend from the inside of the electrode assembly 2 in the showerhead 24 through the connecting element 14 and further outside of the reaction chamber 10 and outside of the vacuum chamber 20 to the gas source. Alternatively, the blocking gas channel 17 can be part of a precursor channel providing precursor to the showerhead 24 and through the precursor supply openings 4 to the reaction zone 15. Thereby the gas source outside the vacuum chamber 20 is a precursor gas source and provide precursor both to the reaction zone 15 and to the gap 6 as the blocking gas. A flow path 8 of the blocking gas when supplied out from the gas supply opening 7 at the upper surface 2a of the electrode assembly 2 in the showerhead 24 extends along the gap 6 parallel to the dielectric layer 5 to the outer perimeter 22 of the electrode assembly 2 and along the outer perimeter surface 2b of the electrode assembly 2 towards the reaction zone 15. The at least one side wall 13 of the reaction chamber 10 comprises also the dielectric layer 5 along the second gap 9 between the side wall 13 and the outer perimeter surface 2b of the electrode assembly 2 of the showerhead 24.

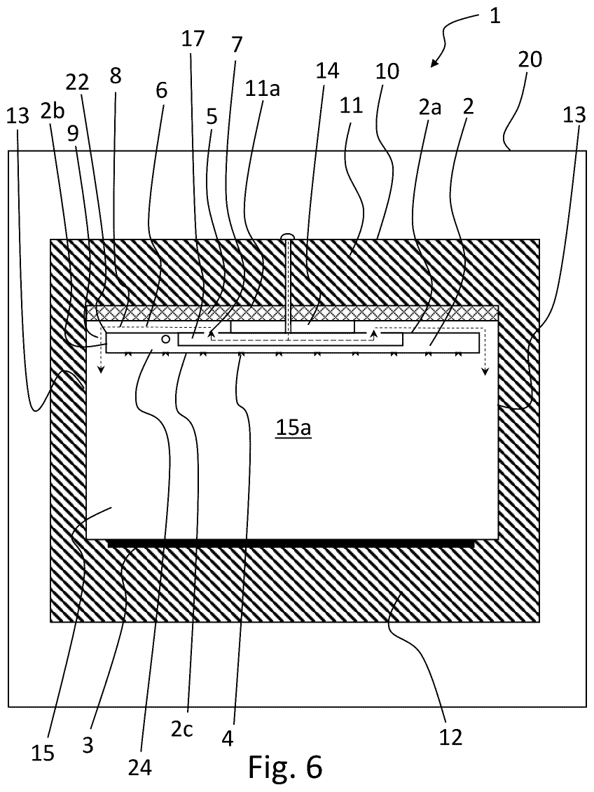

FIG. 6 shows the apparatus 1 according to the invention having the same structural components as described in connection with the FIG. 1 and said to apply to all figures. The apparatus shown in FIG. 6 further comprises a showerhead 24 having the precursor supply opening 4 through which the precursor is supplied to the reaction zone 15 provided between the showerhead 24 and the counter electrode 3 similarly as described in connection with FIG. 5. The showerhead 24 comprises also the electrode assembly 2 having the upper surface 2a, the outer perimeter surface 2b and the under surface 2c. The gas supply opening 7 is formed at the upper surface 2a of the electrode assembly 2 which the gas supply opening 7 opens into the gap 6 for supplying blocking gas from a blocking gas channel 17 to the gap 6. As the electrode assembly 2 is part of the showerhead 24 the blocking gas channel 17 extends inside the showerhead 24 and is in flow connection with a gas source outside the reaction chamber 10 and outside the vacuum chamber 20. The blocking gas channel 17 can extend from the inside of the electrode assembly 2 in the showerhead 24 through the connecting element 14 and further outside of the reaction chamber 10 and outside of the vacuum chamber 20 to the gas source. Alternatively, the blocking gas channel 17 can be part of a precursor channel providing precursor to the showerhead 24 and through the precursor supply openings 4 to the reaction zone 15. Thereby the gas source outside the vacuum chamber 20 is a precursor gas source and provide precursor both to the reaction zone 15 and to the gap 6 as the blocking gas. A flow path 8 of the blocking gas when supplied out from the gas supply opening 7 at the upper surface 2a of the electrode assembly 2 in the showerhead 24 extends along the gap 6 parallel to the dielectric layer 5 to the outer perimeter 22 of the electrode assembly 2 and along the outer perimeter surface 2b of the electrode assembly 2 towards the reaction zone 15.

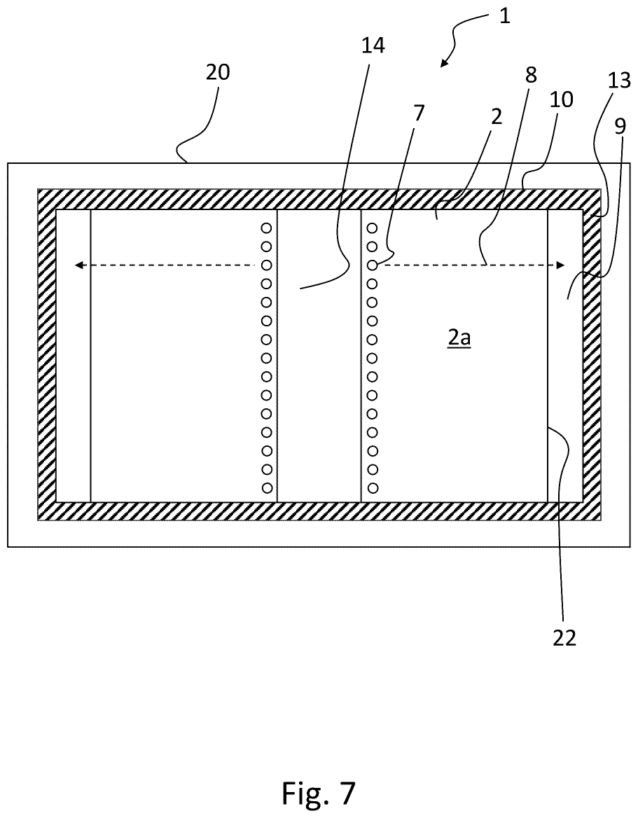

FIG. 7 shows an apparatus 1 according to the invention presented above in a cross-section from the same point as shown in FIG. 2, but with a different geometry. The apparatus 1 has a square geometry in this example having the vacuum chamber 20 around the reaction chamber 10, which the reaction chamber 10 having the side wall 13. The connecting element 14 forms the connection to the top wall of the reaction chamber 10 (not shown in the figure). The electrode assembly 2 has the upper surface 2a along which the blocking gas flows toward the outer perimeter 22 of the electrode assembly 2 and past the outer perimeter 22 of the electrode assembly 2 to a second gap 9 between the at least one side wall 13 and the outer perimeter surface 2b of the electrode assembly 2 (the outer perimeter surface is not shown in this figure but the outer perimeter 22 is shown). In this example the gas supply opening 7 is provided at the upper surface 2a of the electrode assembly 2 next to the connecting element 14. The blocking gas is supplied from the gas supply opening 7 and flows along the gap 6 in flow path 8 toward the outer perimeter 22 of the electrode assembly 2. The flow path 8 extends past the outer perimeter 22 of the electrode assembly 2 where it reaches the second gap 9 extending along the outer perimeter surface 2b of the electrode assembly 2 and along the side wall 13 of the reaction chamber 10.

The invention has been described above with reference to the examples shown in the figures. However, the invention is in no way restricted to the above examples but may vary within the scope of the claims.

1. An atomic layer deposition apparatus for processing a surface of a substrate successively with at least a first precursor and a second precursor according to principles of atomic layer deposition, the apparatus comprising:
a reaction chamber having a top wall, a bottom wall and at least one side wall, said walls forming a reaction space inside the reaction chamber
an electrode assembly arranged in connection with the top wall,
a counter electrode arranged opposite the electrode assembly at a distance from said electrode assembly such that a reaction zone is formed between the electrode assembly and the counter electrode, and
a precursor supply opening via which the precursors are supplied to the reaction space
the apparatus further comprising:
a connecting element arranged between the electrode assembly and the top wall of the reaction chamber such that the electrode assembly is connected to the top wall through the connecting element,
a dielectric layer provided on an inner surface of the top wall of the reaction chamber,
a gap formed between an upper surface of the electrode assembly and the dielectric layer of the inner surface of the top wall of the reaction chamber for providing a flow path for a blocking gas to prevent a precursor film formation between the electrode assembly and the reaction chamber, the gap extending between the connecting element and an outer perimeter of the electrode assembly, and is open to the reaction space through the outer perimeter of the electrode assembly, and
a gas supply opening that opens into the gap for supplying blocking gas from a blocking gas channel to the gap.

2. The atomic layer deposition apparatus according to claim 1, wherein the blocking gas channel is arranged to extend inside the electrode assembly such that the gas supply opening is provided at the upper surface of the electrode assembly through which the blocking gas is supplied from the blocking gas channel to the gap.

3. The atomic layer deposition apparatus according to claim 1, wherein the blocking gas channel is arranged to extend through the top wall of the reaction chamber such that the gas supply opening is provided at the inner surface of the top wall of the reaction chamber having the dielectric layer through which the blocking gas is supplied from the blocking gas channel to the gap.

4. An The atomic layer deposition apparatus according to claim 1, wherein the gas supply opening is arranged closer to the connecting element than the outer perimeter of the electrode assembly.

5. The atomic layer deposition apparatus according to claim 1, wherein the electrode assembly comprises the upper surface which is towards the top wall of the reaction chamber, a under surface which is towards the bottom wall of the reaction chamber and a perimeter surface which is towards the at least one side wall of the reaction chamber,
the electrode assembly is arranged at a distance from the at least one side wall such that the flow path extends from the first gap past the outer perimeter of the upper surface of the electrode assembly to a second gap between the perimeter surface of the electrode assembly and the at least one side wall of the reaction chamber.

6. An The atomic deposition apparatus according to claim 1, wherein the dielectric layer is arranged to extend from the inner surface of the top wall of the reaction chamber to the at least one side wall of the reaction chamber.

7. An The atomic deposition apparatus according to claim 5, wherein the dielectric layer is arranged to extend from the inner surface of the top wall of the reaction chamber to the at least one side wall of the reaction chamber so that the second gap is formed between the dielectric layer at the at least one side wall of the reaction chamber and the perimeter surface of the electrode assembly.

8. The atomic deposition apparatus according to any claim 1, wherein the apparatus further comprises a showerhead for supplying precursors to the reaction space said showerhead comprises the precursor supply opening and the electrode assembly.

9. The atomic deposition apparatus-according to claim 8, wherein the apparatus further comprises a blocking gas channel having a gas supply opening that opens into the gap for supplying blocking gas from the blocking gas channel to the gap, and said blocking gas channel is arranged to extend inside the showerhead such that the gas supply opening is provided at the upper surface of the electrode assembly through which the blocking gas is supplied from the blocking gas channel to the gap.

10. The atomic deposition apparatus according to claim 1, wherein the apparatus further comprises a vacuum chamber, the reaction chamber is arranged inside the vacuum chamber.

11. A method for coating a substrate in a plasma ALD reaction chamber by subjecting a surface of the substrate to successive surface reactions of a first precursor and a second precursor according to the principles of atomic layer deposition in the reaction chamber comprising:
a top wall, a bottom wall and at least one side wall, said walls forming a reaction space inside the reaction chamber, an electrode assembly arranged in connection with the top wall, a counter electrode arranged opposite the electrode assembly at a distance from said electrode assembly, a reaction zone provided between the electrode assembly and the counter electrode, and a precursor supply opening via which the precursors are supplied to the reaction zone, wherein the method comprises:
arranging a substrate in the reaction zone
supplying blocking gas from a blocking gas channel through a gas supply opening to a gap formed between a-an upper surface of the electrode assembly and a dielectric layer provided on an inner surface of the top wall,
supplying precursor from a precursor gas source through the precursor supply opening to the reaction zone,
directing the blocking gas along the gap towards the reaction zone for preventing the precursor from entering the gap, and
generating plasma discharge to the reaction zone with the electrode assembly.

12. The method for processing a substrate according to claim 11, wherein the method further comprises supplying precursor from the precursor gas source to a showerhead having the precursor supply opening and supplying the precursor further from the showerhead through the precursor supply opening to the reaction zone.

13. The method for processing a substrate according to claim 11, wherein the method further comprises supplying the precursor from the precursor source through the blocking gas channel to the gap as the blocking gas, and further supplying the precursor from the precursor source through the precursor supply opening to the reaction zone as a plasma gas.

14. The method for processing a substrate according to claim 12, wherein the method further comprises supplying inert gas from an inert gas source through the blocking gas channel to the gap as the blocking gas.

15. The method for processing a substrate according to claim 14, wherein the reaction chamber is arranged inside a vacuum chamber and, the method further comprises:
supplying inert gas from the vacuum chamber through the top wall of the reaction chamber to the gap.

16. The method for processing a substrate according to claim 14, wherein the method further comprises:
directing the blocking gas along the gap outside from a perimeter of the upper surface of the electrode assembly, and further along a path between an outer perimeter surface of the electrode assembly and the at least one side wall of the reaction chamber towards the reaction zone.

17. The method for processing a substrate according to claim 11, wherein the method is performed with an atomic layer deposition apparatus for processing a surface of a substrate successively with at least a first precursor and a second precursor according to principles of atomic layer deposition, the apparatus comprising:
a reaction chamber having a top wall, a bottom wall and at least one side wall, said walls forming a reaction space inside the reaction chamber,
an electrode assembly arranged in connection with the top wall,
a counter electrode arranged opposite the electrode assembly at a distance from said electrode assembly such that a reaction zone is formed between the electrode assembly and the counter electrode, and
a precursor supply opening via which the precursors are supplied to the reaction space,
the apparatus further comprising:
a connecting element arranged between the electrode assembly and the top wall of the reaction chamber such that the electrode assembly is connected to the top wall through the connecting element,
a dielectric layer provided on an inner surface of the top wall of the reaction chamber,
a gap formed between an upper surface of the electrode assembly and the dielectric layer of the inner surface of the top wall of the reaction chamber for providing a flow path for a blocking gas to prevent a precursor film formation between the electrode assembly and the reaction chamber, the gap extending between the connecting element and an outer perimeter of the electrode assembly, and is open to the reaction space through the outer perimeter of the electrode assembly, and
a gas supply opening that opens into the gap for supplying blocking gas from a blocking gas channel to the gap.
